(19) United States
(12) Patent Application Publication
(10) Pub. No.: US 2020/0150161 A1
(43) Pub. Date: May 14, 2020

(54) SYSTEM COMPONENT IN AN IMAGING SYSTEM

(71) Applicant: Siemens Healthcare GmbH, Erlangen (DE)

(72) Inventors: Thorsten Feiweier, Poxdorf (DE); Michael Köhler, Nürnberg (DE); Helmut Lenz, Oberasbach (DE); Sören Grübel, Erlangen (DE)

(21) Appl. No.: 16/674,267

(22) Filed: Nov. 5, 2019

(30) Foreign Application Priority Data
Nov. 14, 2018 (EP) 18206297.6

(51) Int. Cl. G01R 21/00; G01R 33/36

(52) U.S. Cl. CPC G01R 21/005; G01R 33/36

(57) ABSTRACT

Systems and methods are provided for determining a use of a system component in an imaging system. The imaging system includes a primary side configured to provide power to the system component and a secondary side including the system component that uses the power provided by the primary side during the image sequence. The method includes determining the use of the system component during an imaging sequence, determining a time averaged power provided by the primary side during the imaging sequence, determining a maximum time averaged power that may be provided by the primary side until a temperature limit is reached on the primary side. Further, whether the time averaged power is smaller than the maximum time averaged power is determined.

### CROSS REFERENCE TO RELATED APPLICATIONS

This application claims the benefit of EP18206297.6, filed on Nov. 14, 2018, which is hereby incorporated by reference in its entirety.

### FIELD

Embodiments relate to a method for determining a use of a system component in an imaging system in which at least one image of an object under examination is generated during the imaging sequence.

### BACKGROUND

For the generation of images of an object under examination such as a patient, system components of the imaging systems are used. An example of such a system component may be the amplifier used to generate magnetic field gradients applied in an MR system, the RF amplifier used in an MR system, the power generating unit in an imaging system using x-rays etc. All the system components include some physical limits as the power required to drive the system components is limited and as the power may overheat the system component or any other component involved. There is a need to provide cost effective imaging systems and as a consequence the system components used in the imaging system are configured to an increasing degree such that the system components exhibit more severe limitations regarding their thermal endurance. This, however, might go along with either a decreased image quality or, in order to maintain a desired quality, with longer acquisition times.

The control of the system components in the medical imaging systems may be configured such that the limitations of the system components are considered on the basis of empirical values. In an MR imaging system, there is a system-specific reference gradient amplitude that may be applied during the imaging sequence. The limit of the gradient amplitude is determined such that the MR system is capable of using the gradient amplitude over longer time periods. The reference values of the gradient amplitudes may not directly related to the different hardware components that are required to generate the gradient fields. Depending on the imaging sequence used, different components might become the limiting factor. Based on the empirical values used for specifying the reference gradient amplitudes only, an exact prediction of the heating of the different hardware components used in the MR imaging system is not possible, that entails a more conservative gradient utilization. This, however, may either sacrifice image quality or require longer acquisition times to generate an MR image of a desired quality. Otherwise, it is possible that the heat generated by the power needed to operate the system component stops a running imaging sequence so that the latter has to be repeated with a relaxed utilization of the system component.

DE 10 2008 015 261 B4 and DE 10 2013 204 310 A1 describe methods in which the load of the different hardware components is determined in detail using a model in order to determine an optimized imaging sequence.

This approach, however, is based on a detailed and time-resolved knowledge of the heating characteristic of the hardware component. Only when time-resolved knowledge is available is it possible to estimate and compare the current induced heat against a thermal limit. In many cases, however, the complexity of individual components and interactions are such that a model for the time-resolved heating characteristic based on the actual utilization does not exist. Even in cases where the models are known, the necessary consideration of manufacturing tolerances in the models may lead to a very conservative use of the system components. Furthermore, the models have to identify the initial state of the hardware components, that might turn out not being always available.

The above-mentioned examples show that a use of the system components in an imaging system is not optimized.

### BRIEF SUMMARY AND DESCRIPTION

The scope of the present invention is defined solely by the appended claims and is not affected to any degree by the statements within this summary. The present embodiments may obviate one or more of the drawbacks or limitations in the related art.

Embodiments provide an optimized use of a system component in an imaging system in view of a power or current induced heating.

In an embodiment, a method for determining a use of a system component in an imaging system is provided in which at least one image of an object under examination is generated during the imaging sequence. The imaging system includes a primary side or supply side configured to provide power to the system component resulting in a thermal load on the primary side that must not exceed a predefined temperature limit. The imaging system furthermore includes a secondary side including the system component that uses the power provided by the primary side during the imaging sequence. According to one step of the method the utilization of the system component during the imaging sequence is determined and a time averaged power provided by the primary side during the imaging sequence is determined with the determined utilization of the system component. Furthermore, a maximum time averaged power is determined that may be supplied by the primary side over a duration of at least one imaging sequence while not exceeding the predefined temperature limit. Furthermore, it is determined whether the time averaged power is smaller than the maximum time averaged power. When the time averaged power is not smaller than the maximum time averaged power, the use of the system component during the imaging sequence is adapted until the time averaged power is smaller than the maximum time averaged power.

The utilization of the system component is determined by determining the time averaged power without using any initial states of the system component. Furthermore, the utilization of the system component may be determined without the exact knowledge of a relationship of how the use of the system component during the imaging sequence influences a heating of the primary side.

A first time constant that describes the power induced heating of the primary side when power is fed to the system component may be much longer than the time period in which an output parameter or output quantity of the system component gets switched during the imaging sequence. As the time constant describing the power induced heating may be longer than the time period in which the system component gets switched and needs the power, it is possible to consider an average load or power of the supply side to determine whether the maximum load or power is exceeded or not.

It is possible that an optimized imaging sequence is determined based on the comparison of the time averaged power to the maximum time averaged power such that either the time needed to generate the at least one image or an image quality parameter of the at least one image such as a signal-to-noise ratio, or a contrast-to-noise ratio in a certain region of interest is optimized.

With the determination of the power induced heating based on the average power the imaging sequence may be configured such that the system component is used in such a way that a heating of the primary side below its maximum value is obtained and the heating may be closer to the maximum value of the temperature limit than obtained with other methods, thus improving the utilization of the system component.

For determining the time averaged power, it is possible to determine an average of a parameter representing the heating of the primary side when power is provided to the system component, and when the maximum of the time averaged power is determined it is possible to determine a maximum of the average of the parameter. The parameter is a parameter that characterizes the thermal load on the primary side, for which a maximum may be determined and that may be deduced from a model of how the system component that is used on the secondary side influences the thermal load on the primary side. In case of a resistive load the heating is determined by the power P=I\hat{ }2*R. When a constant resistance is assumed, the resistive load is proportional to the square of the current I. The gradient coils may be approximated as resistive load. The parameter may be the square of the current provided by the primary side during the imaging sequence.

When semiconductor elements are used (e.g. for switching the gradients) such as transistors the thermal losses approximately scale with the average absolute value of the current.

The imaging system may be an MR imaging system configured to generate MR images and the time averaged power provided by the primary side during the MR imaging sequence is determined. The imaging system may also be a computer tomograph (a CT scanner), a tomosynthesis apparatus, or an X-ray apparatus.

The system component may include the magnetic field gradients applied in the MR system during the imaging sequence. The utilization of the magnetic field gradients in the MR imaging sequence may be determined and the time averaged power provided by the primary side to generate the magnetic field gradients in all directions during the imaging sequence may be determined. When the system component considered is the magnetic field gradient, the time period in which the magnetic field gradient is continuously switched is typically in the range of milliseconds. However, the time constant that describes the current or power induced heating of the primary side is typically in the range of several 10 seconds or several minutes. Accordingly, the first time constant is much longer than the time period in which the magnetic field gradient is utilized and switched so that it is possible to use the average of the power or of the square of the current provided by the primary side.

The time averaged power may be determined based on the utilization of the system component and based on a model that translates the temporal variations when using the system component in a load on the primary/supply side needed to drive the system component.

For the magnetic field gradients, the model may describe that primary current is needed to generate a magnetic field gradient in a certain direction having a certain gradient strength and a certain time course.

When the sum of the average currents needed in the different gradient directions is identified an offset current may also be considered that is flowing in the system independent of the fact whether the magnetic field gradient is applied in the imaging sequence or not. The model is based on the current that is needed to apply a magnetic field gradient and the offset current. The offset current takes into account the situation that a certain current is flowing to keep the gradient system components or other system components running even when no actual magnetic field gradient is switched.

The model may furthermore take into account at least one parameter alpha that describes the relationship between the applied magnetic field gradient and the current provided by the primary side when the magnetic field gradient is applied. The average of the squared current is determined taking into account the determined at least one parameter alpha.

The model may use a transfer function that describes how the utilization of the system component translates into the power provided by the primary side and needed by the secondary side to utilize the system component. The transfer function depends on the system component used and may include an exponential transfer function with a time constant in the range of milliseconds. i.e. in the range in which the secondary side uses the power provided by the primary side to switch the system component.

The imaging sequence may be a diffusion imaging sequence used to determine a diffusion property of the object under examination. In diffusion related images higher gradients are used in different gradient directions. The heating due to the high currents may reach the temperature limit. Embodiments may avoid where the temperature limit is exceeded.

A plurality of sequential imaging sequences may be used in the MR system. The utilization of magnetic field gradients applied in the plurality of sequential imaging sequences may be determined taking into account the corresponding time averaged power of each of the plurality of imaging sequences and the maximum of the time averaged current.

During an examination, imaging sequences with high magnetic field gradients and low gradients are used. In most cases the time period in which high magnetic field gradients close to their maximum values are used is small compared to the time constant describing the current induced heating. As a consequence, with the above described method the utilization of magnetic field gradients in the different imaging sequences, for example, in the imaging sequences using high magnetic field gradients may be optimized such that the highest possible gradients and thus the shortest image time may be obtained without exceeding the current or temperature limit of the current limiter.

The time averaged power may be determined by averaging the power provided by the primary side over an averaging period T. The averaging period T is larger than the time period in which the system component is switched during the imaging sequence.

A corresponding imaging system is provided that is configured to generate at least one image of the object under examination during the imaging sequence. The system includes the system component configured to be utilized during the imaging sequence requiring different amounts of power in order to generate the at least one image. The imaging system includes the primary side configured to provide the power to the system component resulting in a thermal load on the primary side that must not exceed a predefined temperature limit. The imaging system includes the secondary side that uses the power provided by the primary side during the imaging sequence. A control unit is provided configured to operate as mentioned above or as discussed in further detail below.

Additionally, a computer program including a program code to be executed by the at least one processing unit of an imaging system is provided. The execution of the program code causes the at least one processing unit to execute a method as explained above or as described in further detail below.

A carrier including the computer program is provided. The carrier is one of an electronic signal, optical signal, radio signal or computer readable storage medium.

### BRIEF DESCRIPTION OF THE DRAWINGS

FIG. 1 depicts an example schematic view of an MR system configured to determine an optimized use of a system component such as the magnetic field gradients during an imaging sequence.

FIG. 2 depicts an example schematic view of how a primary side with a current limiter provides the current to a system component provided on a secondary side configured to generate the magnetic field gradients.

FIG. 3 depicts an example schematic view of a flowchart of a method carried out by the MR system of FIG. 1.

### DETAILED DESCRIPTION

In the following, embodiments are described in detail with reference to the accompanying drawings. The drawings are to be regarded as being schematic representations, and elements illustrated in the drawings are not necessarily shown to scale. Rather, the various elements are represented such that their function and general purpose becomes apparent to a person skilled in the art. Any connection or coupling between functional blocks, devices, components of physical or functional units depicted in the drawings and described hereinafter may be implemented by an indirect connection or coupling. A coupling between components may be established over a wired or wireless connection. Functional blocks may be implemented in hardware, software, firmware, or a combination thereof.

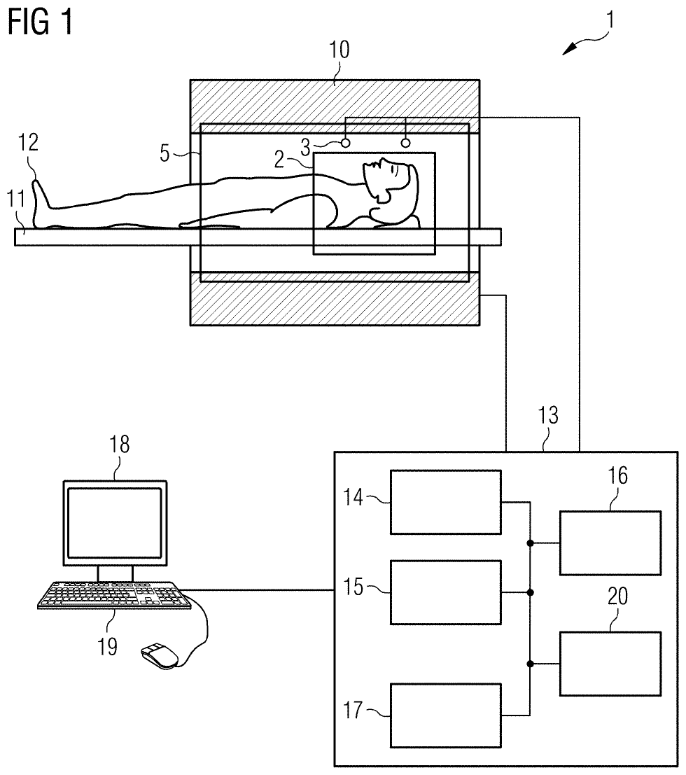

FIG. 1 depicts a schematic view of an MR system 1 that is configured to provide an operating mode in which the use of a system component such as the RF amplifier or the use of the magnetic field gradients is optimized such that a temperature limit of a current limiter configured to provide the current to the magnetic field gradients is not exceeded.

The MR system 1 includes a magnet 10 generating a polarization field B0. An object under examination 12 lying on a table 11 is moved into the center of the MR system 1 where MR signals of the RF-excitation may be detected by a receiving coil 2. One example of a gradient coil 5 is depicted that is able to generate a magnetic field gradient in one direction. Several of the gradient coils may be provided to generate the magnetic field gradients in different directions. A transmitting coil 3 is depicted that is configured to transmit RF pulses into the object under examination. By applying RF pulses and magnetic field gradients, the nuclear spins in the object 12 are excited and the currents induced by the relaxation is detected. The way how MR images are generated and how MR signals are detected using a sequence of RF pulses and a sequence of magnetic field gradients are known.

The MR system 1 includes a controller 13 that is used for controlling the MR system. The controller or control module 13 includes a gradient control unit 14 for controlling and switching the magnetic field gradients, an RF control unit 15 for controlling and generating the RF pulses for the imaging sequence. An imaging sequence control unit 16 is provided that controls the sequence of the applied RF pulses and the magnetic field gradients and thus controls the gradient control unit 14 into the RF control unit 15. In a memory 17 computer programs needed for operating the MR system and the imaging sequences necessary for generating the MR images may be stored together with the generated MR images. The generated MR images may be displayed on a display 18. An input unit 19 may be provided used by users of the MR system to control the functioning of the MR system. A processing unit 20 is provided and may coordinate the operation of the different functional units shown in FIG. 1 and may include one or more processors that may carry out instructions stored on the memory 17. The memory 17 may include the program code to be executed by the processing unit 20. As will be described below the controller 13 and/or the processing unit 20 may be configured such that the use of the magnetic field gradients is determined based on a model that employs the application or time course of the magnetic field gradients in the imaging sequence and translates the use into a current provided to the MR system, for example, the gradient amplifiers.

The MR system may be a spectroscopic MR system that is configured to detect MR signals of the object under examination without generating an image, but for generating spectroscopic data of the object under examination. The system component on the primary side may be the RF unit generating the RF pulses needed to excite the MR signal or the gradient unit in case of a single voxel spectroscopy.

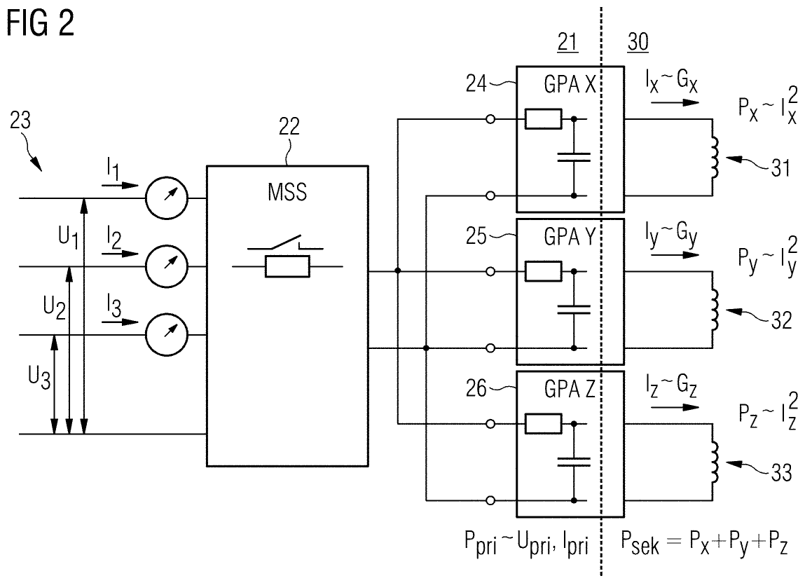

FIG. 2 depicts a more detailed view of some of the components of the MR system 1 of FIG. 1. The MR system includes a primary side 21. The primary side is configured to provide the currents or power needed by the different gradient coils 31, 32, and 33 on the secondary side 30. On the primary side the gradient amplifiers 24, 25, and 26 are depicted that provide the currents needed to generate the magnetic field gradients on the secondary side provided by the different gradient coils. The gradient amplifiers 24 to 26 are the elements receiving the power form the primary side and translate it to the secondary side. FIG. 2 also depicts a protective switch 22 that symbolizes that the primary side may only provide current or power up to a certain limit that is mainly due to the heating of components (such as the switch 22 or other components) used at the primary side to generate the currents. Thus switch 22 is not necessarily provided but indicates in the present example that when a certain heat is generated and a certain temperature is reached on the primary side, the primary side stops to provide the current needed to drive the gradient coils 31 to 34 on the secondary side.

The protective switch 22 is configured such that it passes current to the secondary side until a certain temperature limit is reached within the protective switch 22. Thus, the protective switch 22 plays the role of a current limiter that limits the current that may be provided to the secondary side over time. The idea described below is based on that the time constant that describes the current induced heating of the protective switch 22 or the heating of the primary side itself is much longer than the time period in which the different gradient coils 31, 32, and 33 are switched during the imaging sequence to obtain the magnetic field gradients that are needed for the spatial encoding of the signals. There is no need to exactly identify the relationship between the actual use of the gradient coils and the thermal heating of the current limiter 22 provided on the primary side. As will be described below a model is used that is configured to determine a load parameter on the primary side that is needed to drive the magnetic field gradient based on the exact switching of the magnetic field gradients as identified from the used imaging sequence.

Embodiments make use of a time-averaged power as load parameter that is used by the magnetic field gradient and the maximum time averaged power that may be provided by the primary side over time and as a result determine optimized imaging sequences that may be used by the MR imaging system without exceeding the temperature limit on the primary side.

Furthermore, the knowledge may be used how a pause in the imaging sequence influences the heating of the current limiter.

The model described below and discussed above in connection with FIG. 2 uses the current source 23, and the protective switch 22 to determine the average current. With the model it is possible to predict the average current that has to be provided by the primary side so that the average current may be compared to the average maximum current that may be provided by the protective switch 22 before a temperature limit of protective switch is reached.

The current needs of this part of the MR system depend on the switching of the magnetic field gradients by the imaging sequence. The switching of the current on the secondary side named as I_{X}, I_{Y} and I_{Z} for the three axes X, Y, Z of the gradient system leads to a current on the primary side named I₁, I₂, and I₃ in FIG. 2 that is distributed by the primary side to the different axes. I₁, I₂, and I₃ describe the 3 phases of a three-phase current supply. However other power supplies may be used, and there is not necessarily a relationship between current phase and gradient direction. The use of the gradient amplifiers 24 to 26 may be seen as a power transformation, and might include a temporal filtering of the primary current, by way of example with an exponential transfer function C(t), C(t)=1/T_{C} exp(−t/T_{C}) in which the time constant T_{C} is typically in the range of 10-100 milliseconds. The translation of a magnetic field gradient on the secondary side into a current on the primary side for each of the axes is described by a factor α(j) with j corresponding to the different axes X, Y, and Z.

The square of the current on the primary side Iₚᵣᵢ that is summed over the three different phases may be described as follows:

I²ₚᵣᵢ(t)=(I_{Offset}+I_{Grad}(t))² (1)

An offset current I_{offset} is assumed that describes the current that is used by the gradient or MR system even when no actual magnetic field gradient is applied in the imaging sequence. Furthermore, a gradient related current I_{Grad} is considered that depends on the actual switching of the magnetic field gradients and that may be mathematically described—assuming a transfer function as explained above—with a convolution as shown in the following equation:

I_{Grad}(t)=Σ_{j=x,y,z}αⱼGⱼ²(t)⊕C(t) (2)

The above equations show that the load on the primary side is scaling with the fourth power of the current on the secondary side. It is also possible to include alpha into the transfer function and to consider axis-specific transfer functions.

The time constants on the primary side, here the time constants of the protective switch 22 are in the range of several 10 seconds until several minutes and describe the time constant of the current induced heating until a maximum temperature limit is obtained at which the current limiter interrupts the provision of currents. The time constant is much longer than the time period in which the magnetic field gradients are switched on which is in the range of milliseconds before they are switched off and switched on again. Accordingly, when considering the relevant thermal load on the primary side, it is sufficient to only take into account average values as shown in the following equation:

<I²ₚᵣᵢ>=1/T₀∫^{T}dtI²ₚᵣᵢ(t) (3)

The averaging time T used in equation 3 is much longer than the time period in which a single gradient is switched on before it is switched off again. The averaging time T is selected such that the resulting average value as determined by equation 3 does not depend on the fact which time period in a temporal evolution of the imaging sequence is selected to do the averaging. The time period T is in the same range as the time period describing the current induced heating on the primary side.

The average of the square current as determined by equation 3 is then compared to a maximum value, determined by the maximum temperature under which the protective switch 22 is operating without interrupting the current provided to the secondary side. When the average square of the current is lower than the square of the maximum current, the imaging sequence may get executed with the determined use of the magnetic field gradients. If not, an adaptation of the magnetic field gradients may be necessary, either by introducing further pauses into the imaging sequence or by reducing the amplitude of the magnetic field gradients.

In the example given above actual values of I_{offset} and the parameter a are needed. Those values may be determined directly from the design of the gradient components. If this is not possible or too complex, it is also possible to determine both parameters by calibration measurements. Two different currents provided by the primary side are measured when different imaging sequences are executed on the secondary side with a known switching pattern of magnetic field gradients. It should be understood that the current used in the two different imaging sequences should differ by a certain amount in order to have different calibration points. With the knowledge of the used magnetic field gradients G_{x,y,z}(t) it is possible to determine the needed parameters. Differences between the different gradient axes may either be determined by averaging based on an assumption that a similar switching pattern is used on each axis or may be determined using a relative scaling when the differences for the different gradient axes are known. Furthermore, it is possible to obtain a separate calibration for each gradient axis.

With the model, the knowledge of the switching of the magnetic field gradients in the imaging sequence and the calibration it is possible to determine the currents that have to be provided by the primary side. If the currents and thus the current induced heating are larger than the threshold provided by the current limiter, the imaging sequence may be adapted accordingly. By way of example it is possible to introduce a pause of a certain time period into the imaging sequence so that the time needed to carry out the imaging sequence is increased. As an alternative, or in addition, the amplitudes of the magnetic field gradients may be reduced.

One possible field of application is the use of the above method in diffusion imaging in which diffusion properties of a certain part of the examined body are determined. For diffusion imaging high magnetic field gradients are required that get successively switch along different directions that may lead to a large load on the primary side. However, as the time periods in which the diffusion gradients are switched on are comparatively short, the above described method may get applied. Accordingly, it is possible to determine in advance whether an image acquisition with the selected gradient switching will be possible without exceeding the temperature limit. This provides the calculation of valid parameter ranges for b-values, echo times TE or repetition times TR, and to limit the selection of parameters to the ranges. The user of the system may thus only select the parameter within the predetermined range that limits the maximum heat load and assures that the temperature limit is not exceeded. In order to stay within the temperature limit, it may be necessary to increase the echo time TE that leads to a smaller gradient for a certain b-value and thus to a smaller current, wherein the longer TE may lead to a smaller signal-to-noise ratio. As an alternative it may be necessary to increase the repetition time TR that increases the measurement duration but that also leads to a reduced current below the limit on the primary side.

The aforementioned approach may also be used when several sequential imaging sequences are applied to the object under examination. In an MR imaging of an object under examination, different imaging sequences are used, some of them have high gradient demand whereas others have lower gradient demand. As long as the time periods of the actual switching of the magnetic field gradients is much shorter than the time constant describing the current induced heating and as long as the overall time of the imaging sequences with large magnetic field gradient demand is shorter than the time constant describing the current induced heating, the above described method may increase the performance of the whole MR system.

As far as the calibration is concerned, the calibration may be determined for each individual MR imaging system before delivery or during installation, or for each type of the MR imaging system.

By way of example, the type-specific calibration relating to a certain type of MR imaging systems, e.g. having a certain magnetic field strength or certain gradient components may be carried out in the factory and pre-coded into the system so that a calibration is not necessary each time a system gets installed.

For components that contain complex electric circuitries, it might turn out that the precision of the model predictions depends on the actual type of imaging sequences. By way of example the prediction of the required currents with high precision might be possible either for sequences with strong magnetic field gradient variations or for nearly constant magnetic field gradients, and this may depend on the fact whether the calibration was obtained with one or the other type of sequences. The calibration may be determining, for example, for the class of imaging sequences for which the reaching of the temperature limit is highly likely. Different calibrations may be carried out for the different classes of imaging sequences.

If the MR systems is used in such a way that the user may only select imaging parameters within a parameter range by which the limits of the current limiter is not exceeded, it may be necessary to determine and predict the temperature induced heating very quickly. Certain assumptions for the calculation of the magnetic field gradients may be used. By way of example, a normal gradient pulse may have a trapezoidal form with an amplitude G, a ramp time TR and a constant maximum value during T_{D}. The trapezoidal shapes may be simplified with a gradient having a square shape with a certain amplitude G and a switching time T_{K}. The time period T_{K} may be determined based on T_{R} and T_{D} such that the resulting current need corresponds to the actual use of the currents. By way of example time period T_{K} may be determined as follows:

T_{K}=T_{R}*⅔+TD (4)

Furthermore, it is possible to take into account the use of a pause within the imaging sequence. If the average load is described as an integral over the load B(t), then B is determined as follows:

B=1/T₀∫^{T}dtB(t) (5)

A pause of the duration TP leads to the following average load B′:

B′=1/(T+TP)₀∫^{T+TP}dtB(t)=1/(T+TP)₀∫^{T}dtB(t)=BT/(T+TP) (6)

Based on the knowledge of the average load B and the time period T, it is possible to directly determine the pause needed to stay below the limit Bₘₐₓ≥B′.

The way how a pause influences the mean load may be determined numerically. It is possible to introduce longer and shorter pauses into the imaging sequence and then to determine the average load.

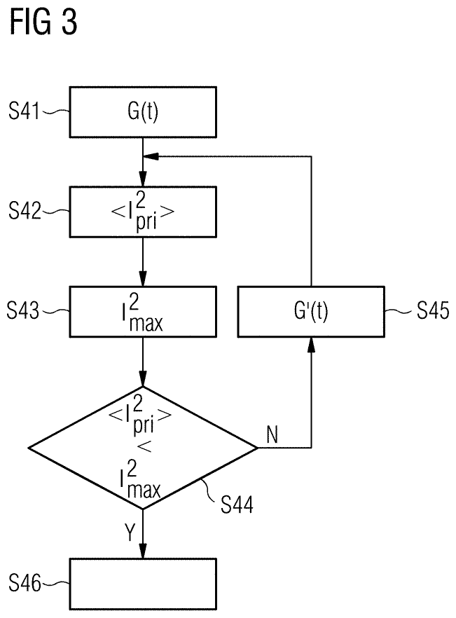

FIG. 3 depicts a method for use of the system components such as the magnetic field gradients in an imaging system. In step S41 the use of the system component during the imaging sequence is determined. In the example given above it is the exact switching of the different magnetic field gradients over time during the imaging sequence. In step S42 the square of the average current provided by the primary side for the determined use is calculated, e.g. based on a model that may translate the used gradient into a current provided by the primary side. In the example above the model is described in the above equations (1) to (3). Furthermore, in step S43 the square of the maximum current that may be provided by the primary side without overheating the primary side is determined. The maximum value may be either determined from data sheets of the manufacturer of the installed electric components or may be determined based on experiments in which for a defined gradient switching the amplitude of the gradient is increased step by step while detecting the current or power provided by the primary side. When the system switches off or when a measured temperature of a component exceeds the limit specified by its manufacturer, the maximum average current or power is found. In step S44 it is determined whether the average current is smaller than the maximum current wherein the determination is based on the square of the two values. If this is not the case the use of the system component has to be adapted in step S45 as symbolized by G′(T) and the calculation of steps S42 to S44 is repeated with the adapted use of the system component. If step S44 indicates that the temperature limit is not reached the imaging sequence may be used in step S46 with the determined use of the gradient as determined in step S41. In a further embodiment it may also be determined in step S44 how close the square of the primary current is to the square of the maximum current and the imaging sequence may be adapted such that either the time is minimized that is used for applying the imaging sequence with the conditions that the square of the primary current is smaller than the square of the maximum current limit. As an alternative, the imaging sequence may be such that a certain quality parameter such the signal-to-noise ratio, contrast-to-noise ratio in a certain part of the image is optimized by using larger magnetic field gradients or higher values of the system component without exceeding the current limit.

Summarizing the above described method makes it possible to operate the MR system close to the temperature limits without exceeding them. Accordingly, the imaging system may be operated without interrupting the measurements due to the fact that temperature limits by the system components have been exceeded.

The use of the average values makes it possible to model very complex relationships. Furthermore, as discussed, the current provided by the primary side is determined based on a model. The model may additionally use the characteristics of the gradient amplifier by using calibration measurements in order to determine a relation between the current used by the secondary side to switch the system component and the current provided by the primary side.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for determining a utilization of a system component in an imaging system in which at least one image of an object under examination is generated during an imaging sequence, the imaging system comprising a primary side configured to provide power to the system component resulting in a thermal load on the primary side that must not exceed a predefined temperature limit, and a secondary side comprising the system component that utilizes the power provided by the primary side during the image sequence, the method comprising:
determining the utilization of the system component during the imaging sequence,
determining a time averaged power supplied by the primary side during the imaging sequence with the determined utilization;
determining a maximum time averaged power that may be supplied by the primary side over a duration of at least one imaging sequence while not exceeding the predefined temperature limit; and
determining whether the time averaged power is smaller than the maximum time averaged power, wherein when the time averaged power is not smaller than the maximum time averaged power, configuring the use of the system component during the imaging sequence until the time averaged power is smaller than the maximum time averaged power.

2. The method of claim 1 wherein the time averaged power is determined as a function of where a first time constant that describes a power induced heating of the primary side when power is supplied to the system component is longer than a time period in which the system component is continuously utilized during the imaging sequence.

3. The method of claim 1, wherein the utilization of the system component is determined without identifying a relationship of how the use of the system component during the imaging sequence influences a heating of the primary side.

4. The method of claim 1, further comprising:
determining an optimized imaging sequence based on a comparison of the time averaged power to the maximum time averaged power such that a time needed to generate the at least one image, an image quality parameter of the at least one image, or the time needed to generate the at least one image and the image quality parameter of the at least one image is optimized for the imaging sequence.

5. The method of claim 1, wherein determining the time averaged power comprises determining an average of a parameter describing a heating of the primary side when power is provided to the system component, and determining the maximum time averaged power comprises determining a maximum of the average of the parameter.

6. The method according to claim 5, wherein the parameter is a square of a current provided by the primary side during the imaging sequence.

7. The method of claim 1, wherein the imaging system is an MR system configured to generate MR images, wherein the time averaged power provided by the primary side during the imaging sequence is determined when the time averaged power is determined.

8. The method of claim 7, wherein the system component comprises a gradient field generating unit used to generate magnetic field gradients applied in the MR system, wherein the utilization of the magnetic field gradients in the imaging sequence is determined and an average of a square current provided by the primary side to set up the magnetic field gradients during the imaging sequence is determined.

9. The method of claim 7, wherein the square current is determined taking into account an offset current which is flowing independent of whether magnetic field gradients are applied in the imaging sequence.

10. The method of claim 8, further comprising:
determining at least one parameter a describing a relationship between the applied magnetic field gradients and a current provided by the primary side when the magnetic field gradient is applied, wherein the average of the square current is determined taking into account the determined at least one parameter a.

11. The method of claim 7, wherein the imaging sequence is a diffusion imaging sequence used to determine a diffusion property in the object under examination.

12. The method of claim 7, wherein a plurality of sequential imaging sequences are used in the MR system, wherein a utilization of magnetic field gradients applied in the plurality of sequential imaging sequences is determined taking into account a corresponding time averaged power for each of the plurality of imaging sequences and the maximum time averaged power.

13. The method of claim 1, wherein the time averaged power is determined by averaging the power provided by the primary side over an averaging period T, wherein the averaging period is larger than a time period in which the system component is continuously switched during the imaging sequence.

14. The method of claim 1, wherein the time averaged power is determined based on the utilization of the system component based on a model which translates the utilization of the system component in the power needed to use the system component.

15. An imaging system configured to generate at least one image of an object under examination during an imaging sequence, the system comprising:
a system component configured to be switched on and off during the imaging sequence in order to generate the at least one image;
a primary side configured to provide power to the system component, resulting in a thermal load on the primary side which must not exceed a predefined temperature limit;
a secondary side comprising the system component that is configured to use the power provided by the primary side during the imaging sequence; and
a control unit configured to:
determine a utilization of the system component during the imaging sequence;
determine a time averaged power supplied by the primary side during the imaging sequence with the determined utilization;
determine a maximum time averaged power that may be supplied by the primary side over a duration of at least one imaging sequence while not exceeding the predefined temperature limit;
determine whether the time averaged power is smaller than the maximum time averaged power, wherein when the time averaged power is not smaller than the maximum time averaged power, adapting the use of the system component during the imaging sequence until the time averaged power is smaller than the maximum time averaged power.

16. The imaging system of claim 15, wherein the control unit determines the time averaged power as a function of where a first time constant that describes a power induced heating of the primary side when power is supplied to the system component is longer than a time period in which the system component is continuously utilized during the imaging sequence.

17. The imaging system of claim 15, wherein the utilization of the system component is determined without identifying a relationship of how the use of the system component during the imaging sequence influences a heating of the primary side.

18. The imaging system of claim 15, wherein the control unit is further configured to determine an optimized imaging sequence based on a comparison of the time averaged power to the maximum time averaged power such that a time needed to generate the at least one image, an image quality parameter of the at least one image, or the time needed to generate the at least one image and the image quality parameter of the at least one image is optimized for the imaging sequence.

19. A non-transitory computer implemented storage medium that stores machine-readable instructions executable by at least one processor, the machine-readable instructions comprising:
determining a utilization of a system component in an imaging system in which at least one image of an object under examination is generated during an imaging sequence, the imaging system comprising a primary side configured to provide power to the system component resulting in a thermal load on the primary side that must not exceed a predefined temperature limit, and a secondary side comprising the system component that utilizes the power provided by the primary side during the image sequence;
determining a time averaged power supplied by the primary side during the imaging sequence with the determined utilization;
determining a maximum time averaged power that may be supplied by the primary side over a duration of at least one imaging sequence while not exceeding the predefined temperature limit; and
determining whether the time averaged power is smaller than the maximum time averaged power, wherein when the time averaged power is not smaller than the maximum time averaged power, configuring the use of the system component during the imaging sequence until the time averaged power is smaller than the maximum time averaged power.

20. The non-transitory computer implemented storage medium of claim 19, wherein determining the time averaged power comprises determining an average of a parameter describing a heating of the primary side when power is provided to the system component, and determining the maximum time averaged power comprises determining a maximum of the average of the parameter.
